(19) United States
(12) Patent Application Publication
(10) Pub. No.: US 2025/0029927 A1
(43) Pub. Date: Jan. 23, 2025

(54) SEMICONDUCTOR PACKAGE

(71) Applicant: SAMSUNG ELECTRONICS CO., LTD., Suwon-si (KR)

(72) Inventor: YOUNGBAE KIM, Suwon-si (CN)

(73) Assignee: SAMSUNG ELECTRONICS CO., LTD., Suwon-si (KR)

(21) Appl. No.: 18/419,266

(22) Filed: Jan. 22, 2024

(30) Foreign Application Priority Data
Jul. 17, 2023 (KR) 10-2023-0092409

(51) Int. Cl. H01L 23/538; H01L 23/00; H01L 23/498; H01L 25/065

(52) U.S. Cl. CPC H01L 23/5381; H01L 23/49816; H01L 23/49822; H01L 24/08; H01L 24/16; H01L 25/0652; H01L 2224/08146; H01L 2224/08155; H01L 2224/16165; H01L 2224/16235; H01L 2924/1431; H01L 2924/1435; H01L 2924/15311

(57) ABSTRACT

A semiconductor package includes a package substrate, a first device on the package substrate and a second device on the package substrate and horizontally spaced apart from the first device, where the package substrate includes a first redistribution layer, a second redistribution layer on the first redistribution layer, a core section between the first redistribution layer and the second redistribution layer, a dummy structure in the first redistribution layer and on a bottom surface of the core section and a bridge chip in the second redistribution layer and on a top surface of the core section, and where a thermal conductance of the dummy structure is greater than a thermal conductance of the first redistribution layer.

### CROSS-REFERENCE TO RELATED APPLICATION

This application is based on and claims priority under 35 U.S.C § 119 to Korean Patent Application No. 10-2023-0092409, filed on Jul. 17, 2023 in the Korean Intellectual Property Office, the disclosure of which is incorporated herein by reference in its entirety.

### BACKGROUND

The present disclosure relates to a semiconductor package and a method of fabricating the same.

Demand for electronic products having high performance, high speed, and compact size is increasing. To meet the trend, there has recently been developed a packaging technology in which a plurality of semiconductor chips are mounted in a single package.

To meet such demands, reduction in size and weight of electronic parts mounted on the portable devices is required. In order to accomplish the reduction in size and weight of the electronic parts, there is need for technology to integrate a number of individual devices into a single package as well as technology to reduce individual sizes of mounting parts.

### SUMMARY

One or more example embodiments provide a semiconductor package which may have improved thermal radiation efficiency and increased operating reliability.

Further, one or more example embodiments provide a semiconductor package which may have improved electrical properties.

Additional aspects will be set forth in part in the description which follows and, in part, will be apparent from the description, or may be learned by practice of the presented embodiments.

According to an aspect of an example embodiment, a semiconductor package may include a package substrate, a first device on the package substrate and a second device on the package substrate and horizontally spaced apart from the first device, where the package substrate includes a first redistribution layer, a second redistribution layer on the first redistribution layer, a core section between the first redistribution layer and the second redistribution layer, a dummy structure in the first redistribution layer and on a bottom surface of the core section and a bridge chip in the second redistribution layer and on a top surface of the core section, and where a thermal conductance of the dummy structure is greater than a thermal conductance of the first redistribution layer.

According to an aspect of an example embodiment, a semiconductor package may include a package substrate, a first device on the package substrate and a second device on the package substrate, where the package substrate includes a first redistribution layer, a second redistribution layer on the first redistribution layer, a core section between the first redistribution layer and the second redistribution layer, the core section including a central region and a peripheral region at least partially surrounding the central region, a plurality of central through vias vertically penetrating the core section in the central region, a plurality of peripheral through vias vertically penetrating the core section in the peripheral region, a dummy structure in the first redistribution layer and contacting a bottom surface of the core section, and a bridge chip in the second redistribution layer and contacting a top surface of the core section, where a first width of each of the plurality of central through vias is greater than a second width of each of the plurality of peripheral through vias and a thermal conductance of each of the plurality of central through vias is greater than a thermal conductance of each of the plurality of peripheral through vias.

According to an aspect of an example embodiment, a semiconductor package may include a package substrate, a first semiconductor chip on the package substrate, a chip stack on the package substrate and horizontally spaced apart from the first semiconductor chip, the chip stack including a plurality of second semiconductor chips that are vertically stacked, and a molding layer on the package substrate, the molding layer at least partially surrounding the first semiconductor chip and the chip stack, where the package substrate includes a core section, a plurality of through vias vertically penetrating the core section, a first redistribution layer on a bottom surface of the core section, a bridge chip on a top surface of the core section, and a second redistribution layer at least partially covering the bridge chip and the top surface of the core section, and where a thermal conductance of the bridge chip is greater than a thermal conductance of the second redistribution layer.

### BRIEF DESCRIPTION OF DRAWINGS

The above and other aspects, features, and advantages of certain example embodiments of the present disclosure will be more apparent from the following description taken in conjunction with the accompanying drawings, in which:

FIG. 1 is a cross-sectional view illustrating a semiconductor package according to one or more embodiments of the disclosure;

FIGS. 2 to 5 are cross-sectional views illustrating a package substrate of a semiconductor package according to one or more embodiments of the disclosure;

FIG. 6 is a cross-sectional view illustrating a semiconductor package according to one or more embodiments of the disclosure; and

FIGS. 7 to 10 are cross-sectional views illustrating a method of fabricating a semiconductor package according to one or more embodiments of the disclosure.

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms.

As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

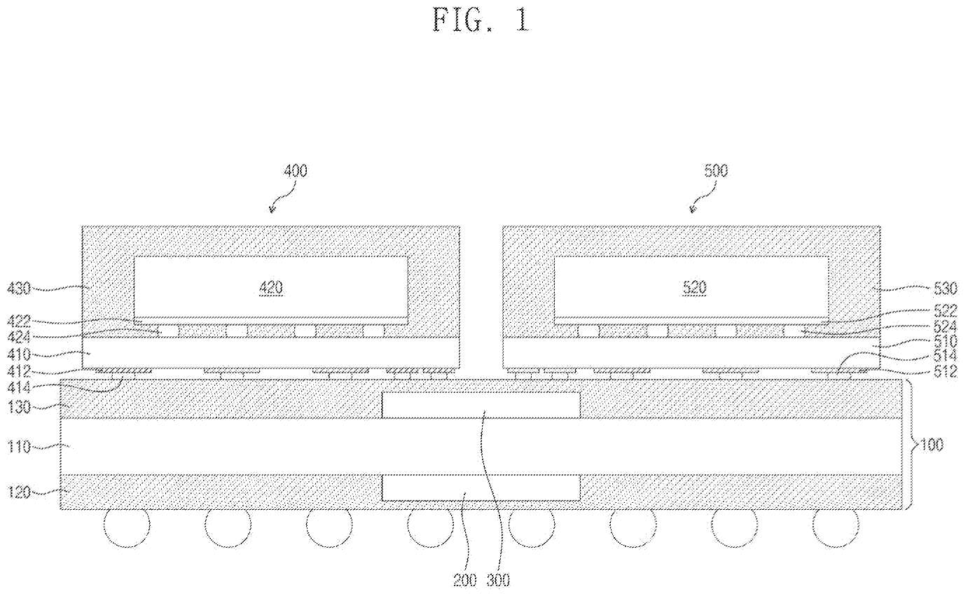

FIG. 1 a cross-sectional view illustrating a semiconductor package according to one or more embodiments of the disclosure.

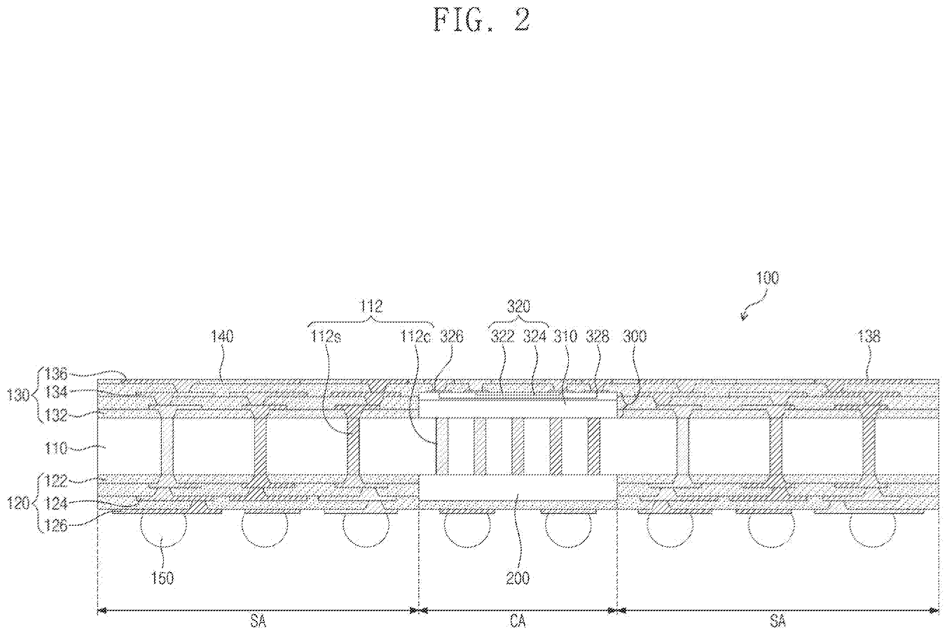

FIGS. 2 to 5 are cross-sectional views illustrating a package substrate depicted in FIG. 1 of a semiconductor package according to one or more embodiments of the disclosure.

Referring to FIGS. 1 and 2, a package substrate 100 may be provided. The package substrate 100 may include a core section 110, a first redistribution layer 120 provided on a bottom surface of the core section 110, and a second redistribution layer 130 provided on a top surface of the core section 110.

The core section 110 may have a plate shape. In a plan view, the core section 110 may include one core pattern. The core section 110 may include a central region CA and a peripheral region SA. The central region CA of the core section 110 may be defined to indicate an area where a dummy structure 200 and a bridge chip 300 are attached to the core section 110 (e.g., where a surface of a dummy structure 200 contacts a bottom surface of the core section 110, and where a surface of the bridge chip 300 contacts a top surface of the core section 110). The peripheral region SA of the core section 110 indicate an area other than the central region CA in the core section 110. The core section 110 may include a dielectric material. For example, the core section 110 may include glass.

The core section 110 may include through vias 112 that vertically penetrate the core section 110. The through vias 112 may extend from the top surface of the core section 110 toward the bottom surface of the core section 110. The through vias 112 may be exposed on the top surface of the core section 110 and on the bottom surface of the core section 110. The through vias 112 may include a conductive material. For example, the through vias 112 may include a metallic material, such as copper (Cu), aluminum (Al), and tungsten (W). The through vias 112 may include central through vias 112c in the central region CA of the core section 110 and peripheral through vias 112s in the peripheral region SA of the core section 110.

The peripheral through vias 112s may be provided between the first redistribution layer 120 and the second redistribution layer 130 which will be discussed below. The peripheral through vias 112s may connect the first redistribution layer 120 and the second redistribution layer 130 to each other in the peripheral region SA of the core section 110. Electrical signals and heat may be transferred through the peripheral through vias 112s in a direction from upper toward lower portions of the package substrate 100.

The central through vias 112c may be provided between the first redistribution layer 120 and the second redistribution layer 130 which will be discussed below. In the central region CA of the core section 110, the central through vias 112c may be provided between a dummy structure 200 in the first redistribution layer 120 and a bridge chip 300 in the second redistribution layer 130. Electrical signals and heat may be transferred through the central through vias 112c in a direction from upper toward lower portions of the package substrate 100. The central through vias 112c will be further described in detail below.

The first redistribution layer 120 may be provided on the bottom surface of the core section 110. The first redistribution layer 120 may be a component for redistribution of the package substrate 100. The first redistribution layer 120 may cover or at least partially cover the bottom surface of the core section 110. The first redistribution layer 120 may include one or more first wiring layers that are sequentially stacked on the bottom surface of the core section 110. The first wiring layer may include a first dielectric pattern 122 and a first wiring pattern 124. The first wiring pattern 124 of one first wiring layer may be electrically connected to the first wiring pattern 124 of an adjacent first wiring layer. The first dielectric pattern 122 and the first wiring pattern 124 will be described below based on the one first wiring layer.

The first dielectric pattern 122 may include a dielectric polymer or a photo-imagable dielectric (PID). For example, the PID may include at least one selected from photosensitive polyimide, polybenzoxazole (PBO), phenolic polymers, and benzocyclobutene polymers.

The first wiring pattern 124 may be provided on the bottom surface of the first dielectric pattern 122. The first wiring pattern 124 may protrude into the bottom surface of the first dielectric pattern 122. The first wiring pattern 124 may extend horizontally on the bottom surface of the first dielectric pattern 122. On the bottom surface of the first dielectric pattern 122, the first wiring pattern 124 may be covered or at least partially covered by another dielectric pattern. The first wiring pattern 124 may be a line or pad part of the first wiring layer. For example, the first wiring pattern 124 may be a component for horizontal redistribution in the first redistribution layer 120. The first wiring pattern 124 may include a conductive material. For example, the first wiring pattern 124 may include copper (Cu).

The first wiring pattern 124 may have a damascene structure. For example, the first wiring pattern 124 may include a via that protrudes into a top surface thereof. The via may be a component for vertical connection between the first wiring patterns 124 of neighboring wiring layers. For example, the via may extend from the top surface of the first wiring pattern 124, and may penetrate the first dielectric pattern 122 to be coupled to a bottom surface of the first wiring pattern 124 of overlying another wiring layer. A lower portion of the first wiring pattern 124 disposed below the first dielectric pattern 122 may be a head portion used as a horizontal wiring line or pad, and the via of the first wiring pattern 124 may be a tail portion. The first wiring pattern 124 may have an inverse T shape.

External terminals 150 may be provided below the first redistribution layer 120. The external terminals 150 may be disposed on lower pads 126 provided on a bottom surface of the first redistribution layer 120. The lower pads 126 may be a portion of the first wiring pattern 124 exposed on the bottom surface of the first redistribution layer 120, or may be discrete pads disposed on the first dielectric pattern 122 of the first redistribution layer 120 and connected to the first wiring pattern 124. The external terminals 150 may include solder balls or solder bumps.

A dummy structure 200 may be provided in the first redistribution layer 120. The dummy structure 200 may be provided on the bottom surface of the core section 110 (i.e., a top surface of the dummy structure 200 may contact the bottom surface of the core section 110). On the bottom surface of the core section 110, the dummy structure 200 may be covered or at least partially covered by the first dielectric pattern 122. The dummy structure 200 may have a thickness greater than that of at least one of the first wiring layers. The dummy structure 200 may be provided in the central region CA of the core section 110. The dummy structure 200 may not be electrically connected to the first wiring pattern 124. For example, in the first dielectric pattern 122, the dummy structure 200 may be spaced apart from the first wiring pattern 124 and electrically floated.

A first adhesion layer may be interposed between a top surface of the dummy structure 200 and the bottom surface of the core section 110. The dummy structure 200 may be attached to the bottom surface of the core section 110 by the first adhesion layer. The first adhesion layer may include a die attach adhesive (DAA).

The second redistribution layer 130 may be provided on the top surface of the core section 110. The second redistribution layer 130 may cover or at least partially cover the top surface of the core section 110. The second redistribution layer 130 may include one or more second wiring layers that are sequentially stacked on the top surface of the core section 110. The second wiring layer may include a second dielectric pattern 132 and a second wiring pattern 134. The second wiring pattern 134 may be electrically connected to the second wiring pattern 134 of an adjacent another second wiring layer. The second dielectric pattern 132 and the second wiring pattern 134 will be described below based on one second wiring layer.

The second dielectric pattern 132 may include a dielectric polymer or a PID. The PID may include, for example, at least one selected from photosensitive polyimide, PBO, phenolic polymers, and benzocyclobutene polymers.

The second wiring pattern 134 may be provided on a top surface of the second dielectric pattern 132. The second wiring pattern 134 may protrude into the top surface of the second dielectric pattern 132. The second wiring pattern 134 may extend horizontally on the top surface of the second dielectric pattern 132. On the top surface of the second dielectric pattern 132, the second wiring pattern 134 may be covered or at least partially covered by an overlying another second dielectric pattern 132. The second wiring pattern 134 may be a line or pad portion of the second wiring layer. For example, the second wiring pattern 134 may be a component for horizontal redistribution in the second redistribution layer 130. The second wiring pattern 134 may include a conductive material. For example, the second wiring pattern 134 may include copper (Cu).

The second wiring pattern 134 may have a damascene structure. For example, the second wiring pattern 134 may include a via that protrudes onto a bottom surface thereof. The via may be a component for vertical connection between the second wiring patterns 134 of neighboring second wiring layers. For example, the via may extend from the bottom surface of the second wiring pattern 134, and may penetrate the second dielectric pattern 132 to be coupled to a top surface of the second wiring pattern 134 of an underlying another second wiring layer. An upper portion of the second wiring pattern 134 disposed on the second dielectric pattern 132 may be a head portion used as a horizontal wiring line or pad, and the via of the second wiring pattern 134 may be a tail portion. The second wiring pattern 134 may have a T shape.

The second wiring patterns 134 may be electrically connected through the peripheral through vias 112s to corresponding first wiring patterns 124. The peripheral through vias 112s may have top surfaces that are correspondingly connected to the bottom surfaces of the second wiring patterns 134 in a lowermost second wiring layer, and may also have bottom surfaces that are correspondingly connected to the top surfaces of the first wiring patterns 124 in an uppermost first wiring layer. For example, the first redistribution layer 120 and the second redistribution layer 130 may be electrically connected through the peripheral through vias 112s.

The second redistribution layer 130 may be provided with first and second upper pads 136 and 138 on a top surface thereof. The first and second upper pads 136 and 138 may be a portion of the second wiring pattern 134 exposed from the second dielectric pattern 132 of the second redistribution layer 130, or may be discrete pads disposed on the second dielectric pattern 132 of the second redistribution layer 130 and connected to the second wiring pattern 134. The first and second upper pads 136 and 138 may include a conductive material. For example, the first and second upper pads 136 and 138 may include copper (Cu).

A substrate protection layer 140 may be provided on the top surface of the second redistribution layer 130. The substrate protection layer 140 may cover or at least partially cover an uppermost second wiring layer. The substrate protection layer 140 may cover or at least partially cover the second dielectric pattern 132 and surround or at least partially surround the first and second upper pads 136 and 138. The first and second upper pads 136 and 138 may be exposed on a top surface of the substrate protection layer 140. The substrate protection layer 140 may include a dielectric polymer or a PID. The substrate protection layer 140 may not be provided in some embodiments.

The bridge chip 300 may be provided in the second redistribution layer 130. The bridge chip 300 may be provided on the top surface of the core section 110. The bridge chip 300 may be provided in the central region CA of the core section 110. In the second redistribution layer 130, the bridge chip 300 may be covered or at least partially covered by the second dielectric pattern 132. The bridge chip 300 may have a thickness greater than that of a certain second wiring layer.

The bridge chip 300 may have a front surface and a rear surface. In this description, the term “front surface” may be defined to indicate an active surface of an integrated element in a semiconductor chip, a surface on which wiring lines are formed, or a surface on which pads of a semiconductor chip are formed, and the term “rear surface” may be defined to indicate a surface opposite to the front surface. The rear surface of the bridge chip 300 may face the core section 110. For example, the bridge chip 300 may be disposed in a face-up state on the core section 110. The front surface of the bridge chip 300 may also be referred to herein as the “top surface” of the bridge chip 300, and the rear surface of the bridge chip 300 may also be referred to herein as the “bottom surface” of the bridge chip 300. The bridge chip 300 may be attached to the top surface of the core section 110 by a second adhesion layer. For example, the second adhesion layer may be interposed between a bottom surface of the bridge chip 300 and the top surface of the core section 110. The second adhesion layer may include a DAA. The bridge chip 300 may include a bridge substrate 310 and a bridge circuit layer 320. The bridge substrate 310 may include a semiconductor substrate. For example, the bridge substrate 310 may be a semiconductor substrate such as a semiconductor wafer. The bridge substrate 310 may be a silicon (Si) substrate, a silicon-on-insulator (SOI) substrate, a germanium (Ge) substrate, a germanium-on-insulator (GOI) substrate, a silicon-germanium (SiGe) substrate, a III-V group semiconductor substrate, or an epitaxial film substrate obtained by performing selective epitaxial growth (SEG).

The bridge circuit layer 320 may be provided on a top surface of the bridge substrate 310. For example, the bridge circuit layer 320 may include a bridge dielectric pattern 322 and a bridge circuit pattern 324 that are formed on the top surface of the bridge substrate 310. In one or more embodiments, the bridge circuit layer 320 may further include a circuit pattern or a protection layer.

The bridge dielectric pattern 322 may include a dielectric material. The bridge dielectric pattern 322 may include silicon oxide (SiO), silicon nitride (SiN), silicon oxynitride (SiON), silicon carbonitride (SiCN), or a dielectric polymer.

The bridge circuit pattern 324 may be provided in the bridge dielectric pattern 322. The bridge circuit pattern 324 may be a component for electrical connection between various semiconductor devices mounted on the core section 110. For example, the bridge circuit pattern 324 may be a component for electrical connection between a first device 400 and a second device 500 which will be described below. The bridge circuit pattern 324 may include a conductive material. For example, the bridge circuit pattern 324 may include copper (Cu) or aluminum (Al).

FIG. 2 depicts that the bridge dielectric pattern 322 is one layer, but the disclosure is not limited thereto. The bridge dielectric pattern 322 may have a plurality of dielectric layers, and the bridge circuit pattern 324 may be a wiring pattern provided in the plurality of dielectric layers.

A first bridge pad 326 and a second bridge pad 328 may be provided on a top surface of the bridge chip 300. The first bridge pad 326 and the second bridge pad 328 may be disposed on a top surface of the bridge circuit layer 320. The first bridge pad 326 and the second bridge pad 328 may protrude into the top surface of the bridge chip 300. The disclosure, however, is not limited thereto, and the first bridge pad 326 and the second bridge pad 328 may be a portion of the bridge circuit pattern 324 and may be provided in the bridge dielectric pattern 322. In this case, the first bridge pad 326 and the second bridge pad 328 may be exposed on the top surface of the bridge dielectric pattern 322. The first bridge pad 326 and the second bridge pad 328 may be disposed on different areas of the bridge chip 300. For example, the first bridge pad 326 may be disposed on a first area, and the second bridge pad 328 may be disposed on a second area. For example, the bridge circuit pattern 324 may connect the first bridge pad 326 and the second bridge pad 328 that are positioned on different areas. The first bridge pad 326 may be electrically connected to the second bridge pad 328 through the bridge circuit pattern 324 provided in the bridge circuit layer 320.

The central through vias 112c may be disposed between the bridge chip 300 and the dummy structure 200. Each of the central through vias 112c may contact the bottom surface of the bridge chip 300 and a top surface of the dummy structure 200. The central through vias 112c may provide heat transfer paths along which heat is transferred to the dummy structure 200 from external apparatuses and from the bridge chip 300. The central through vias 112c may be heat transfer vias along which the heat is transferred through the dummy structure 200 toward a lower portion of the package substrate 100. The central through vias 112c may receive the heat from the bridge chip 300. In an embodiment, the central through vias 112c may be electrically insulated from the first and second wiring patterns 124 and 134. For example, the central through vias 112c may be electrically insulated from the first and second redistribution layers 120 and 130.

A material of the bridge chip 300 may be the same as that of the dummy structure 200. The material of the bridge chip 300 may indicate a material of the bridge substrate 310 having a volume that is greater than that of any other material of the bridge chip 300. The bridge chip 300 may have a thermal conductance greater than that of the second redistribution layer 130. In addition, the dummy structure 200 may have a thermal conductance greater than that of the first redistribution layer 120. The term “thermal conductance” may refer to the degree to which a substance having a specific shape and size actually transfers heat. The thermal conductance of the bridge chip 300 may refer to an average thermal conductance of materials included in the bridge chip 300 (this may apply to the thermal conductance of the first redistribution layer 120 and the thermal conductance of the second redistribution layer 130). Heat concentrated on the bridge chip 300 and heat generated from external apparatuses may be easily and sequentially transferred through the central through vias 112c and the dummy structure 200 toward a lower portion of the package substrate 100. Therefore, a semiconductor package may have improved thermal radiation efficiency and increased operating reliability.

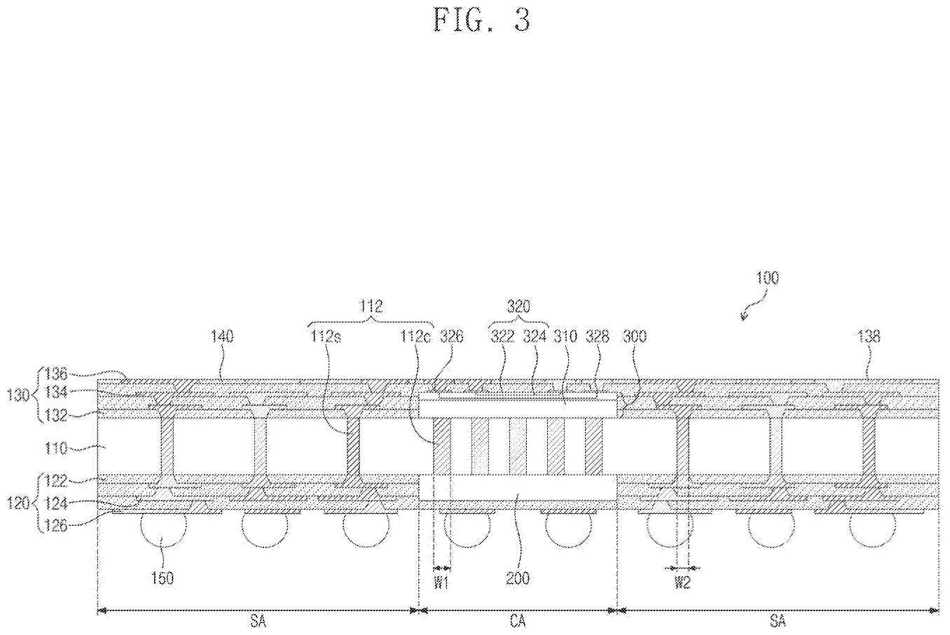

Referring to FIG. 3, the central through via 112c may have a thermal conductance greater than that of the peripheral through via 112s. In embodiments where substances are formed of a material having the same thermal conductance (which may be inherent properties of the substances), an increase in area of a cross-section perpendicular to a heat transfer direction in the substance may induce an increase in actual thermal conductance. For example, the central through via 112c may be provided to have a large width. The central through via 112c may have a first width W1 greater than a second width W2 of the peripheral through via 112s. Therefore, the thermal conductance of the central through via 112c may be greater than that of the peripheral through via 112s. Accordingly, an amount of heat transfer through the central through vias 112c may be greater than that of heat transfer through the peripheral through vias 112s. Thus, the heat transfer efficiency along a vertical direction of the core section 110 in the package substrate 100 may be improved.

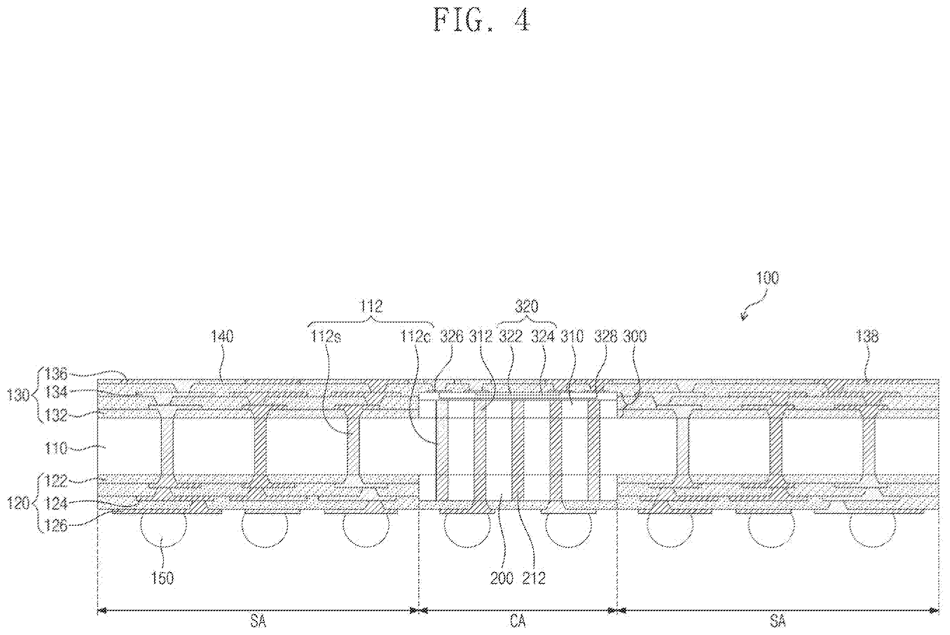

According to one or more embodiments, first vertical connection terminals 212 may be further included to vertically penetrate the dummy structure 200. As shown in FIG. 4, the first vertical connection terminals 212 may extend from a bottom surface of the dummy structure 200 toward a top surface of the dummy structure 200. The first vertical connection terminals 212 may be exposed on the bottom surface of the dummy structure 200 and on the top surface of the dummy structure 200. The first vertical connection terminals 212 may be electrically connected to the central through vias 112c. The first vertical connection terminals 212 may be directly connected to corresponding central through vias 112c. Alternatively, when a first adhesion layer is provided between the dummy structure 200 and the core section 110, connection terminals may be additionally provided between the top surface of the dummy structure 200 and the bottom surface of the core section 110, and thus the first vertical connection terminals 212 may be correspondingly connected through the connection terminals to the central through vias 112c.

The first vertical connection terminals 212 may be electrically connected to the first wiring pattern 124. FIG. 4 depicts that portions of the first wiring pattern 124 is connected to some of the central through vias 112c, but the disclosure is not limited thereto. The bridge circuit pattern 324 may be electrically connected to an entirety of the central through vias 112c.

Second vertical connection terminals 312 may further be included to vertically penetrate the bridge substrate 310 in the bridge chip 300. The second vertical connection terminals 312 may extend from a bottom surface of the bridge substrate 310 toward the top surface of the bridge substrate 310. The second vertical connection terminals 312 may be exposed on the bottom surface of the bridge substrate 310 and on the top surface of the bridge substrate 310. The second vertical connection terminals 312 may be electrically connected to the central through vias 112c. The second vertical connection terminals 312 may be directly connected to corresponding central through vias 112c. Alternatively, when a second adhesion layer is provided between the bridge chip 300 and the core section 110, connection terminals may be additionally provided between the bottom surface of the bridge chip 300 and the top surface of the core section 110, and thus the second vertical connection terminals 312 may be correspondingly connected through the connection terminals to the central through vias 112c.

The second vertical connection terminals 312 may be electrically connected to the bridge circuit pattern 324. FIG. 4 depicts that a portion of the bridge circuit pattern 324 is connected to one of the central through vias 112c, but the disclosure is not limited thereto. The bridge circuit pattern 324 may be electrically connected to an entirety of the central through vias 112c.

According to one or more embodiments of the disclosure, heat concentrated on the bridge chip 300, or the bridge circuit pattern 324, and heat generated from external apparatuses may be easily transferred toward a lower portion of the package substrate 100 through the first and second vertical connection terminals 212 and 312 and the central through vias 112c. Therefore, heat transfer efficiency may be improved along a vertical direction of the package substrate 100. In addition, the first and second vertical connection terminals 212 and 312 and the central through vias 112c may serve as transfer paths for electrical connection. Accordingly, a semiconductor package may improve in electrical properties.

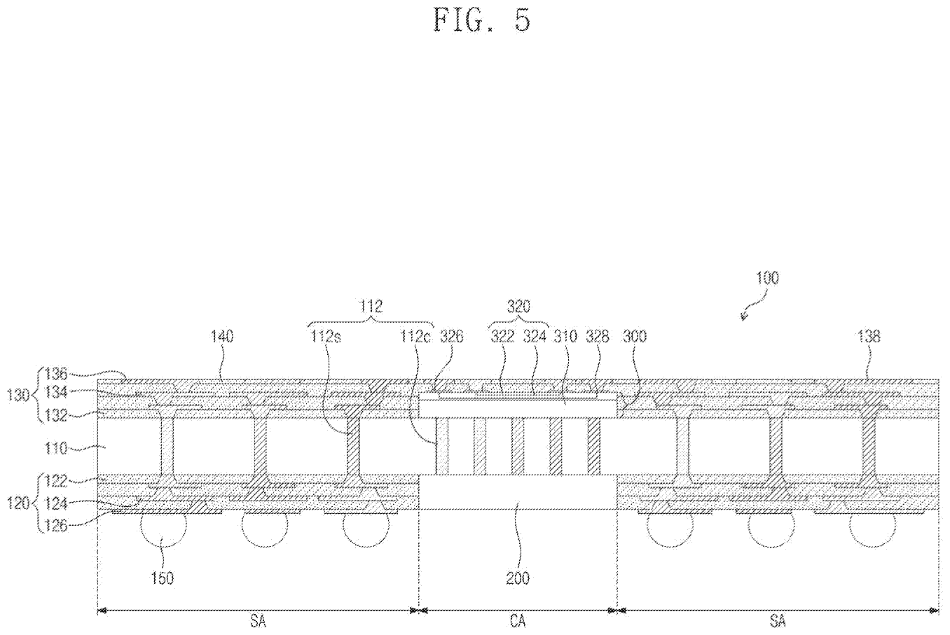

According to one or more embodiments, for easy transfer of heat in the package substrate 100 toward a lower portion of the package substrate 100, the bottom surface of the dummy structure 200 may be exposed on the bottom surface of the first redistribution layer 120. As shown in FIG. 5, on the bottom surface of the core section 110, the first dielectric pattern 122 may surround or at least partially surround the dummy structure 200. A thermal radiation structure may further be provided on the exposed bottom surface of the dummy structure 200. The thermal radiation structure may be attached through an adhesion film to the bottom surface of the dummy structure 200. The thermal radiation structure may include a heat sink. As the thermal radiation structure is provided on the bottom surface of the dummy structure 200, there may be an increase in efficiency of heat transfer through the dummy structure 200 toward a lower portion of the package substrate 100.

Referring to FIG. 1, a first device 400 may be provided on the package substrate 100. The first device 400 may be a semiconductor package. For example, the first device 400 may include a first substrate 410, a first semiconductor chip 420, and a first molding layer 430.

The first substrate 410 may be a printed circuit board (PCB). Alternatively, the first substrate 410 may be a redistribution layer. The first substrate 410 may include first device pads 412 disposed on a bottom surface of the first substrate 410.

The first semiconductor chip 420 may be disposed on the first substrate 410. The first semiconductor chip 420 may include a first circuit layer 422 provided in a lower portion of the first semiconductor chip 420. The first circuit layer 422 may include integrated circuits, and the integrated circuits may include a memory circuit, a logic circuit, or a combination thereof. For example, the first semiconductor chip 420 may be a logic chip or a memory chip.

The first semiconductor chip 420 may be mounted on the first substrate 410. For example, the first semiconductor chip 420 may be provided on its bottom surface with first chip terminals 424 electrically connected to the first circuit layer 422. The first chip terminals 424 may be coupled to pads provided on a top surface of the first substrate 410. The pads may be the first upper pads 136 discussed with reference to FIG. 2. FIG. 1 depicts that the first semiconductor chip 420 is flip-chip mounted on the first substrate 410, but the disclosure is not limited thereto. For example, the first semiconductor chip 420 may be wire-bond mounted on the first substrate 410.

The first substrate 410 may be provided thereon with the first molding layer 430 that covers or at least partially covers the first semiconductor chip 420. The first molding layer 430 may include a dielectric polymer, such as an epoxy-based polymer.

FIG. 1 depicts only an example configuration of the first device 400, and the disclosure is not limited thereto. The first device 400 may be a semiconductor package having a plurality of semiconductor chips. Alternatively, the first device 400 may be one semiconductor chip or one semiconductor die. Alternatively, the first device 400 may include various elements, such as an external connector, an input/output component, or a substrate.

The second device 500 may be provided on the top surface of the second redistribution layer 130. On the top surface of the second redistribution layer 130, the second device 500 may be disposed and may be spaced apart from each other. The second device 500 may be a semiconductor package. For example, the second device 500 may include a second substrate 510, a second semiconductor chip 520, and a second molding layer 530.

The second substrate 510 may be a PCB. Alternatively, the second substrate 510 may be a redistribution layer. The second substrate 510 may include second device pads 512 disposed on a bottom surface of the second substrate 510.

The second semiconductor chip 520 may be disposed on the second substrate 510. The second semiconductor chip 520 may include a second circuit layer 522 provided in a lower portion of the second semiconductor chip 520. The second circuit layer 522 may include integrated circuits, and the integrated circuits may include a memory circuit, a logic circuit, or a combination thereof. For example, the second semiconductor chip 520 may be a logic chip or a memory chip.

The second semiconductor chip 520 may be mounted on the second substrate 510. For example, the second semiconductor chip 520 may be provided on the bottom surface with second chip terminals 524 electrically connected to the second circuit layer 522. The second chip terminals 524 may be coupled to pads provided on a top surface of the second substrate 510. The pads may be the second upper pads 138 discussed with reference to FIG. 2. The second semiconductor chip 520 may be coupled through the second chip terminals 524 to pads of the second substrate 510. The second chip terminals 524 may be provided between the pads of the second substrate 510 and chip pads of the second semiconductor chip 520. FIG. 1 depicts that the second semiconductor chip 520 is flip-chip mounted on the second substrate 510, but the disclosure is not limited thereto. For example, the second semiconductor chip 520 may be wire-bond mounted on the second substrate 510.

The second substrate 510 may be provided thereon with the second molding layer 530 that covers or at least partially covers the second semiconductor chip 520. The second molding layer 530 may include a dielectric polymer, such as an epoxy polymer.

FIG. 1 depicts only an example configuration of the second device 500, and the disclosure is not limited thereto. The second device 500 may be a semiconductor package having a plurality of semiconductor chips. Alternatively, the second device 500 may be one semiconductor chip or one semiconductor die. Alternatively, the second device 500 may include various elements, such as an external connector, an input/output component, or a substrate.

Referring to FIGS. 1 to 5, according to one or more embodiments of the disclosure, the package substrate 100 may be provided thereon with external apparatuses such as the first and second devices 400 and 500, and may be provided therein with the bridge chip 300 for electrically connecting the first and second devices 400 and 500 to each other. In order to easily transfer heat generated from the first and second devices 400 and 500 and heat concentrated on the bridge chip 300 toward a lower portion of the package substrate 100, the dummy structure 200 may be provided in the package substrate 100 in the central region CA of the core section 110. In addition, for heat transfer between the bridge chip 300 and the dummy structure 200, the central through vias 112c may be additionally provided in the central region CA of the core section 110. In order to increase in heat transfer efficiency, the bridge chip 300, the dummy structure 200, and the central through vias 112c may have their thermal conductance greater than those of other components disposed nearby. Accordingly, the heat may be sequentially transferred through the bridge chip 300 toward a lower portion of the package substrate 100, the central through vias 112c, and the dummy structure 200, and thus a semiconductor package may have increased thermal radiation efficiency and improved operating reliability.

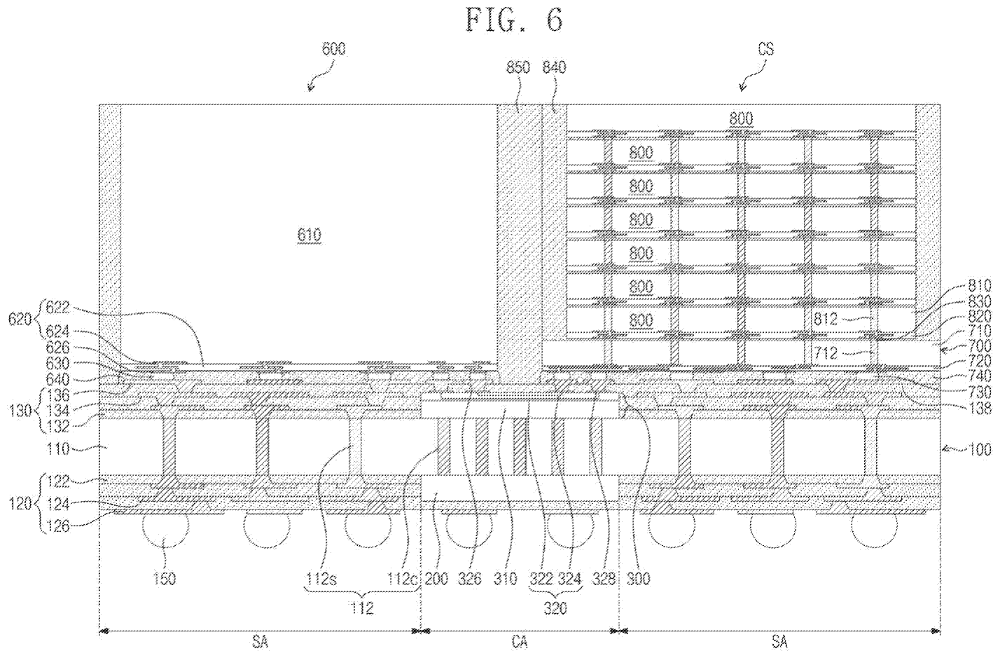

FIG. 6 is a cross-sectional view illustrating a semiconductor package according to one or more embodiments of the disclosure.

Referring to FIG. 6, a package substrate 100 may be provided. For example, the package substrate 100 may include a core section 110, a first redistribution layer 120, a second redistribution layer 130, a dummy structure 200 in the first redistribution layer 120, and a bridge chip 300 in the second redistribution layer 130.

A third semiconductor chip 600 may be provided on the package substrate 100. The third semiconductor chip 600 may have a bottom surface as an active surface. The bottom surface of the third semiconductor chip 600 may be a front surface. The third semiconductor chip 600 may be disposed in a face-down state on the second redistribution layer 130. The third semiconductor chip 600 may include a third semiconductor substrate 610 and a third circuit layer 620.

The third semiconductor substrate 610 may include a semiconductor material. For example, the third semiconductor substrate 610 may include silicon (Si). An integrated element or integrated circuits may be formed on a bottom surface of the third semiconductor substrate 610.

The third circuit layer 620 may be provided on the bottom surface of the third semiconductor substrate 610. The third circuit layer 620 may include a third dielectric pattern 622 and a third circuit pattern 624 provided in the third dielectric pattern 622. On the bottom surface of the third semiconductor chip 600, the third dielectric pattern 622 may cover or at least partially cover the integrated element or the integrated circuits. The third circuit pattern 624 may be coupled to the integrated element or the integrated circuits formed on the third semiconductor substrate 610. The third circuit layer 620 may include a logic circuit. For example, the third semiconductor chip 600 may be a logic chip. Alternatively, the third circuit layer 620 may include a memory circuit. For example, the third semiconductor chip 600 may be a memory chip, such as a dynamic random access memory (DRAM), a static random access memory (SRAM), a magnetic random access memory (MRAM), a Flash memory, etc.

The third semiconductor chip 600 may be mounted on the second redistribution layer 130. For example, the third semiconductor chip 600 may be coupled through third connection terminals 630 to first upper pads 136 and the first bridge pads 326. The third semiconductor chip 600 may be electrically connected to the second redistribution layer 130 and the bridge chip 300 through third connection terminals 630. The third connection terminals 630 may be provided between first pads 626 provided on the bottom surface of the third semiconductor chip 600 and the first upper pads 136 and the first bridge pads 326. The first pads 626 may be provided a portion of the third circuit pattern 624 exposed on the third dielectric pattern 622 of the third circuit layer 620, or discrete pads disposed on the third dielectric pattern 622 of the third circuit layer 620 and connected to the third circuit pattern 624. As the third semiconductor chip 600 is mounted through the third connection terminals 630 on the second redistribution layer 130, the bottom surface of the third semiconductor chip 600 may be spaced apart from the second redistribution layer 130.

A first underfill layer 640 may be provided between the top surface of the second redistribution layer 130 and the bottom surface of the third semiconductor chip 600. The first underfill layer 640 may fill a space between the second redistribution layer 130 and the third semiconductor chip 600, and may surround or at least partially surround the first upper pads 136, the first pads 626, the first bridge pads 326, and the third connection terminals 630.

A chip stack CS may be provided on the package substrate 100. On the package substrate 100, the chip stack CS may be laterally spaced apart from the third semiconductor chip 600. The chip stack CS may include a base chip 700, fourth semiconductor chips 800 stacked on the base chip 700, and a second molding layer 840 that surrounds or at least partially surrounds the fourth semiconductor chips 800. The following will describe in detail a configuration of the chip stack CS.

The base chip 700 may include a base substrate 710. The base substrate 710 may be a semiconductor substrate. For example, the base substrate 710 may be a wafer-level semiconductor substrate formed of a semiconductor material such as silicon (Si). The base chip 700 may have a bottom surface as an active surface. For example, an integrated element or integrated circuits may be formed on the bottom surface of the base substrate 710.

The base chip 700 may include a base circuit layer 720 and a base through via 712. The base circuit layer 720 may be provided on the bottom surface of the base chip 700. The base circuit layer 720 may include the integrated element and the integrated circuits. For example, the base circuit layer 720 may be a memory circuit. For example, the base chip 700 may be a memory chip, such as a DRAM, an SRAM, an MRAM, a Flash memory, etc. Alternatively, the base circuit layer 720 may be a logic circuit. In this case, the base chip 700 may be a logic chip. The base through via 712 may penetrate the base chip 700 in a direction perpendicular to the top surface of the second redistribution layer 130. The base through via 712 and the base circuit layer 720 may be electrically connected to each other.

The base chip 700 may further include a protection layer and fourth connection terminals 730. The protection layer may be disposed on the bottom surface of the base chip 700 to cover or at least partially cover the base circuit layer 720. The protection layer may include silicon oxide (SiO) or silicon nitride (SiN). The fourth connection terminals 730 may be provided on the bottom surface of the base chip 700. The fourth connection terminals 730 may be electrically connected to the integrated element or the integrated circuits of the base circuit layer 720.

The fourth semiconductor chip 800 may be provided on the base chip 700. The fourth semiconductor chip 800 may have a width less than that of the base chip 700. The width of the fourth semiconductor chip 800 and the width of the base chip 700 may be measured in a direction parallel to the top surface of the second redistribution layer 130. The fourth semiconductor chip 800 may include a fourth semiconductor substrate 810, a fourth circuit layer 820, and a through via 812. The fourth semiconductor substrate 810 may be a semiconductor substrate. For example, the fourth semiconductor substrate 810 may include silicon (Si). The fourth circuit layer 820 disposed on a bottom surface of the fourth semiconductor substrate 810 may include a memory circuit. For example, the fourth semiconductor chip 800 may be a memory chip, such as a DRAM, an SRAM, an MRAM, a Flash memory, etc. The through via 812 may penetrate the fourth semiconductor chip 800 in a direction perpendicular to the top surface of the second redistribution layer 130. The through via 812 and the fourth circuit layer 820 may be electrically connected to each other. The fourth semiconductor chips 800 may have a bottom surface as an active surface. A plurality of connection bumps 830 may be provided on the bottom surface of the fourth semiconductor chip 800. The connection bumps 830 may be provided between and electrically connect the base chip 700 and the fourth semiconductor chip 800.

A plurality of fourth semiconductor chips 800 may be provided. For example, a plurality of fourth semiconductor chips 800 may be stacked on the base chip 700. The number of stacked fourth semiconductor chips 800 may be 8 to 32. The connection bumps 830 may be correspondingly provided between the fourth semiconductor chips 800. An uppermost fourth semiconductor chip 800 may not include the through via 812. In addition, the uppermost fourth semiconductor chip 800 may have a thickness greater than those of other fourth semiconductor chips 800 disposed thereunder.

An adhesion layer may be provided between the fourth semiconductor chips 800. The adhesion layer may include a non-conductive film (NCF). The adhesion layer may be interposed between the connection bumps 830 between the fourth semiconductor chips 800 to prevent the occurrence of electrical short between the connection bumps 830.

A second underfill layer 740 may be provided between the second redistribution layer 130 and the chip stack CS. The second underfill layer 740 may fill or at least partially fill a space between the second redistribution layer 130 and the base chip 700, and may surround or at least partially surround the second upper pads 138, the second bridge pads 328, and the fourth connection terminals 730.

The second molding layer 840 may be disposed on a top surface of the base chip 700. The second molding layer 840 may cover or at least partially cover the base chip 700. The second molding layer 840 may surround or at least partially surround the fourth semiconductor chips 800. A top surface of the second molding layer 840 may be coplanar with that of the uppermost fourth semiconductor chip 800. The uppermost fourth semiconductor chip 800 may be exposed on the top surface of the second molding layer 840. The second molding layer 840 may include a dielectric polymer material. For example, the second molding layer 840 may include an epoxy molding compound (EMC).

The chip stack CS may be provided as described above. The chip stack CS may be mounted on the second redistribution layer 130. For example, the chip stack CS may be coupled through the fourth connection terminals 730 to the second upper pad 138 disposed on the top surface of the second redistribution layer 130. The fourth connection terminals 730 may electrically connect the chip stack CS and the second redistribution layer 130 to each other, while contacting a top surface of the second upper pad 138 and a bottom surface of the base circuit layer 720.

A third molding layer 850 may be disposed on the top surface of the second redistribution layer 130. The third molding layer 850 may surround or at least partially surround the fourth semiconductor chip 800, the first underfill layer 640, the chip stack CS, and the second underfill layer 740. The third molding layer 850 may have a top surface coplanar with that of the uppermost fourth semiconductor chip 800 in the chip stack CS, and the uppermost fourth semiconductor chip 800 may be exposed on the top surface of the third molding layer 850. The third molding layer 850 may include a dielectric polymer material. For example, the third molding layer 850 may include an EMC.

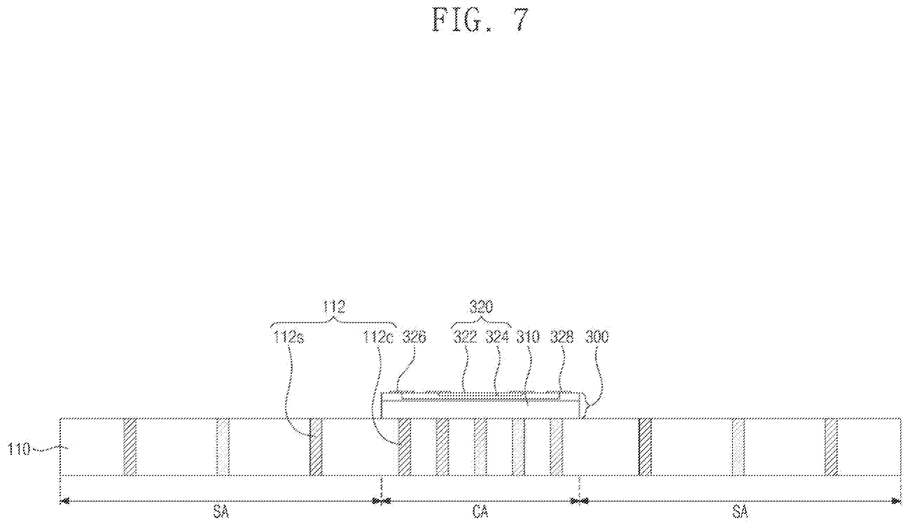

FIGS. 7 to 10 are cross-sectional views illustrating a method of fabricating a semiconductor package according to one or more embodiments of the disclosure.

Referring to FIG. 7, a core section 110 may be provided. Through vias 112 may be formed in the core section 110. For example, the through vias 112 may be formed by forming holes that penetrate the core section 110, and then filling the holes with a conductive material.

A bridge chip 300 may be attached to the core section 110. The bridge chip 300 may be substantially the same as or similar to the bridge chip 300 described above with reference to FIG. 1. The bridge chip 300 may be attached through a second adhesion layer to the core section 110. For example, the second adhesion layer may be attached to a rear surface of the bridge chip 300, and then the bridge chip 300 may be attached to a top surface of the core section 110. In a plan view, the bridge chip 300 may be provided in a central region CA of the core section 110.

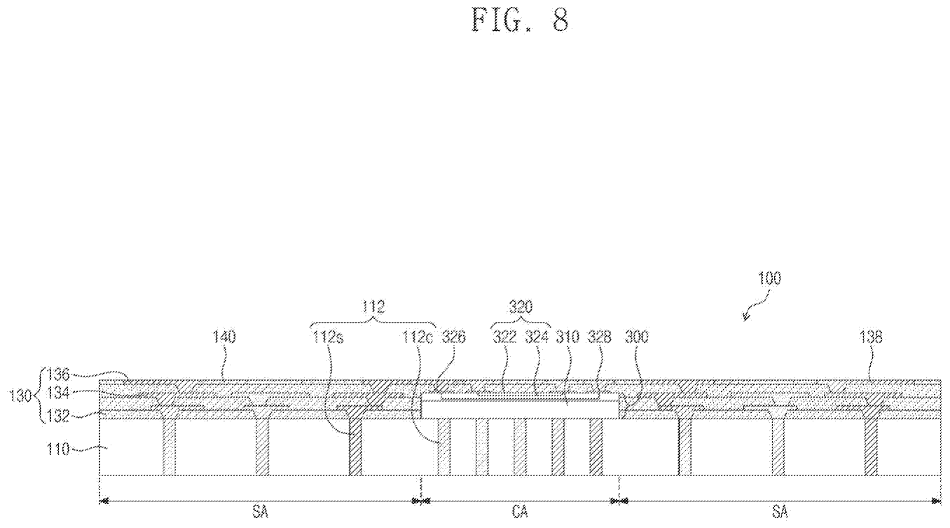

Referring to FIG. 8, a second redistribution layer 130 may be formed on the core section 110. For example, a dielectric layer may be formed on the top surface of the core section 110, and then the dielectric layer may be patterned to form one second dielectric pattern 132. A conductive layer may be formed on the second dielectric pattern 132, and then the conductive layer may be patterned to form one second wiring pattern 134. The formation of the second dielectric pattern 132 and the second wiring pattern 134 may be repeatedly performed. An uppermost dielectric layer of the second redistribution layer 130 may be a substrate protection layer 140, and the second wiring patterns 134 that penetrate the substrate protection layer 140 to be exposed on a top surface of the second redistribution layer 130 may be first and second upper pads 136 and 138. Alternatively, the substrate protection layer 140 and the first and second upper pads 136 and 138 may be separately formed on the top surface of the second redistribution layer 130. For example, a PID layer may be coated on the second dielectric pattern 132 to form the substrate protection layer 140. The substrate protection layer 140 may undergo exposure and development processes to form through holes that expose the second wiring pattern 134. The through holes of the substrate protection layer 140 may be filled with a conductive material to form the first and second upper pads 136 and 138. A plurality of second dielectric patterns 132, a plurality of second wiring patterns 134, the substrate protection layer 140, and the first and second upper pads 136 and 138 may constitute the second redistribution layer 130 described above with reference to FIGS. 1 and 2. The second redistribution layer 130 may be formed to surround or at least partially surround the bridge chip 300. The second redistribution layer 130 may contact lateral and bottom surfaces of the bridge chip 300.

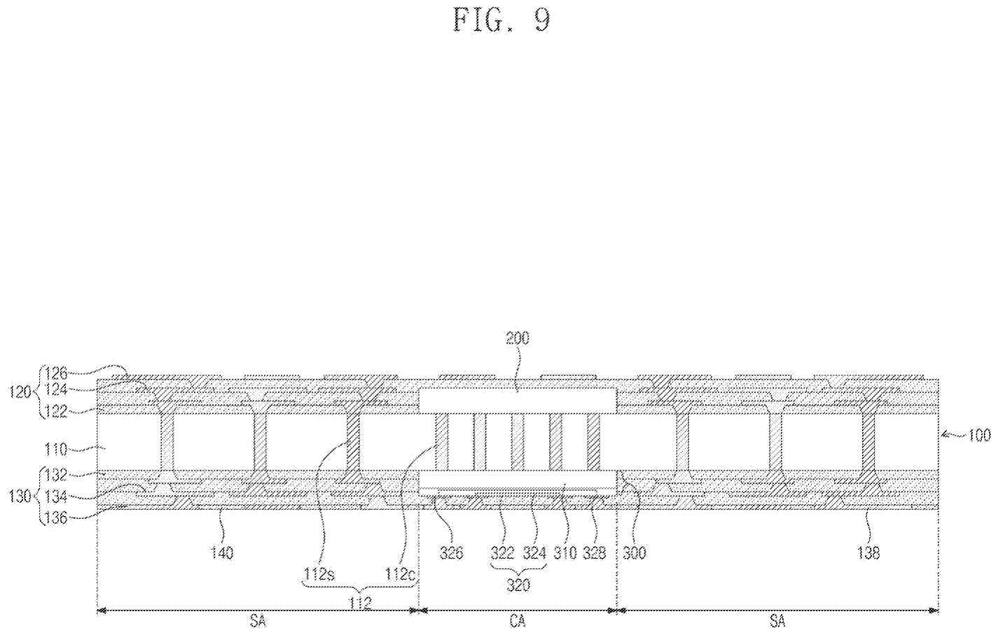

Referring to FIG. 9, a resultant structure of FIG. 8 may be flipped. Thus, the second redistribution layer 130 may be positioned below the core section 110.

A dummy structure 200 may be attached to the core section 110. The dummy structure 200 may be substantially the same as or similar to the dummy structure 200 described above with reference to FIGS. 1 and 2. The dummy structure 200 may be attached through a first adhesion layer to the core section 110. For example, the first adhesion layer may be attached to a bottom surface of the dummy structure 200, and then the dummy structure 200 may be attached to the top surface of the core section 110. The dummy structure 200 and the bridge chip 300 may be opposite to each other across a center of the core section 110. In a plan view, the dummy structure 200 may be positioned in the central region CA of the core section 110.

A first redistribution layer 120 may be formed on the core section 110. For example, a dielectric layer may be formed on the top surface of the core section 110, and then the dielectric layer may be patterned to form one first dielectric pattern 122. A conductive layer may be formed on the first dielectric pattern 122, and then the conductive layer may be patterned to form one first wiring pattern 124. The formation of the first dielectric pattern 122 and the first wiring pattern 124 may be repeatedly performed. Lower pads 126 may be defined to indicate the first wiring patterns 124 exposed on an uppermost first dielectric pattern 122 of the first redistribution layer 120. A plurality of first dielectric patterns 122, a plurality of first wiring patterns 124, and the lower pads 126 may constitute the first redistribution layer 120 described above with reference to FIGS. 1 and 2. The first redistribution layer 120 may be formed to surround or at least partially surround the dummy structure 200. The first redistribution layer 120 may contact lateral and top surfaces of the dummy structure 200.

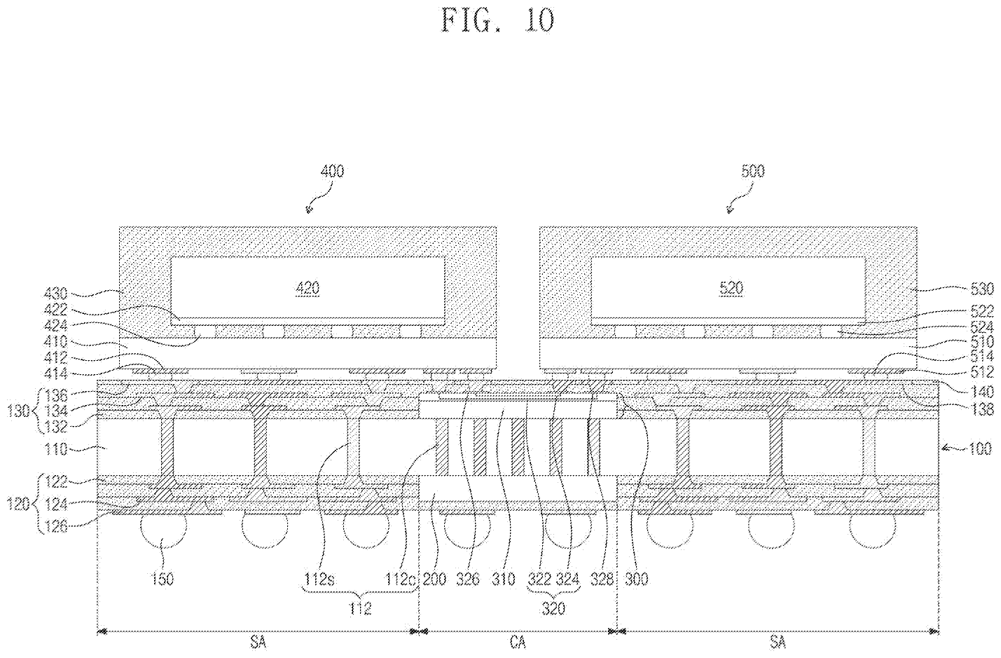

Referring to FIG. 10, on a resultant structure of FIG. 9, external terminals 150 may be disposed on the first redistribution layer 120. The external terminals 150 may be provided on top surfaces of the lower pads 126 exposed on a top surface of the first redistribution layer 120. For example, connection terminals such as solder balls or solder bumps may be attached to the top surfaces of the lower pads 126. After the external terminals 150 are formed by the method described above shown in FIG. 9, the resultant structure may be flipped. The aforementioned method may form a package substrate 100.

A first device 400 and a second device 500 may be disposed on the package substrate 100. The first device 400 may be substantially the same as or similar to the first device 400 described with reference to FIGS. 1 and 2. For example, the first device 400 may include a first substrate 410, a first semiconductor chip 420, and a first molding layer 430. The first substrate 410 may include first device pads 412 disposed on a bottom surface of the first substrate 410.

The first device 400 may be mounted on the package substrate 100. The first device 400 may be placed on the package substrate 100. For example, the first device 400 may be aligned on the package substrate 100 to allow the first device pads 412 to reside on the first upper pads 136. The first device 400 may approach the package substrate 100 to cause first connection terminals 414 to contact the first upper pads 136. Afterwards, the first connection terminals 414 may undergo a soldering process to connect the first connection terminals 414 to the first device pads 412 and the first upper pads 136.

The second device 500 may be substantially the same as or similar to the second device 500 described with reference to FIGS. 1 and 2. For example, the second device 500 may include a second substrate 510, a second semiconductor chip 520, and a second molding layer 530. The second substrate 510 may include second device pads 512 disposed on a bottom surface of the second substrate 510.

The second device 500 may be mounted on the package substrate 100. The second device 500 may be placed on the package substrate 100. For example, the second device 500 may be aligned on the package substrate 100 to allow the second device pads 512 to reside on the second upper pads 138. The second device 500 may approach the package substrate 100 to cause second connection terminals 514 to contact the second upper pads 138. Afterwards, the second connection terminals 514 may undergo a soldering process to connect the second connection terminals 514 to the second device pads 512 and the second upper pads 138.

According to one or more embodiments of the disclosure, heat generated from the first semiconductor chip 420 may be sequentially transferred to the bridge chip 300 through the first chip terminals 424, the first substrate 410, the first connection terminals 414, and the first upper pads 136. In addition, heat generated from the second semiconductor chip 520 may be sequentially transferred to the bridge chip 300 through the second chip terminals 524, the second substrate 510, the second connection terminals 514, and the second upper pads 138. Heat concentrated on the bridge chip 300 and heat generated from the bridge chip 300 may be easily transferred through the central through vias 112c and the dummy structure 200 toward a lower portion of the package substrate 100. Accordingly, a semiconductor package may have improved thermal radiation efficiency and increased operating reliability.

According to one or more embodiments of the disclosure, in order to achieve easy transfer of heat generated from external apparatuses and a bridge chip toward a lower portion of a package substrate, a dummy structure may be inserted into a lower portion of the package substrate. The dummy structure may have a thermal conductance greater than that of a redistribution layer that covers or at least partially covers the dummy structure. Therefore, the heat generated from the external apparatuses and the bridge chip may be easily transferred through the dummy structure toward a lower portion of the package substrate. Accordingly, a semiconductor package may have improved thermal radiation efficiency and increased operating reliability.

In addition, through vias may be disposed between the bridge chip and the dummy structure. The through vias may serve as heat transfer paths along which heat in the package substrate is easily transferred toward a lower portion of the package substrate. Therefore, the through vias may increase heat transfer efficiency in a vertical direction of the package substrate.

Moreover, first vertical connection terminals in the bridge chip and second vertical connection terminals in the dummy structure may be connected to the through vias between the bridge chip and the dummy structure, and thus may serve as heat transfer paths and electrical signal connection paths in a direction from upper toward lower portions of the package substrate. Accordingly, a semiconductor package may improve in electrical properties.

Each of the embodiments provided in the above description is not excluded from being associated with one or more features of another example or another embodiment also provided herein or not provided herein but consistent with the disclosure.

While example embodiments of the disclosure have been particularly shown and described, it will be understood that various changes in form and details may be made therein without departing from the spirit and scope of the following claims.

What is claimed is:

1. A semiconductor package comprising:
a package substrate;
a first device on the package substrate; and
a second device on the package substrate and horizontally spaced apart from the first device,
wherein the package substrate comprises:
a first redistribution layer;
a second redistribution layer on the first redistribution layer;
a core section between the first redistribution layer and the second redistribution layer;
a dummy structure in the first redistribution layer and on a bottom surface of the core section; and
a bridge chip in the second redistribution layer and on a top surface of the core section, and
wherein a thermal conductance of the dummy structure is greater than a thermal conductance of the first redistribution layer.

2. The semiconductor package of claim 1, wherein a material of the bridge chip is the same as a material of the dummy structure.

3. The semiconductor package of claim 1, wherein the second redistribution layer covers the bridge chip over the top surface of the core section.

4. The semiconductor package of claim 1, wherein the first redistribution layer at least partially surrounds the dummy structure, and
wherein at least a portion of a bottom surface of the dummy structure is exposed on a bottom surface of the first redistribution layer.

5. The semiconductor package of claim 1, wherein the first redistribution layer covers the dummy structure over the bottom surface of the core section.

6. The semiconductor package of claim 5, wherein the dummy structure is electrically floated from the first redistribution layer.

7. The semiconductor package of claim 1, wherein the core section comprises:
a central region in which the bridge chip and the dummy structure are provided;
a peripheral region at least partially surrounding the central region;
a plurality of central through vias vertically penetrating the core section in the central region; and
a plurality of peripheral through vias vertically penetrating the core section in the peripheral region.

8. The semiconductor package of claim 7, wherein a first width of each of the plurality of central through vias is greater than a second width of each of the plurality of peripheral through vias.

9. The semiconductor package of claim 7, wherein the plurality of central through vias are electrically insulated from the first redistribution layer and the second redistribution layer.

10. The semiconductor package of claim 7, wherein the bridge chip comprises:
a bridge substrate;
a bridge circuit layer on a top surface of the bridge substrate; and
a plurality of first vertical connection terminals vertically penetrating the bridge substrate and connected to the bridge circuit layer, and
wherein the plurality of first vertical connection terminals are connected to the plurality of central through vias.

11. The semiconductor package of claim 7, wherein the dummy structure comprises a plurality of second vertical connection terminals vertically penetrating the dummy structure, and
wherein the plurality of second vertical connection terminals are connected to the plurality of central through vias.

12. A semiconductor package comprising:
a package substrate;
a first device on the package substrate; and
a second device on the package substrate,
wherein the package substrate comprises:
a first redistribution layer;
a second redistribution layer on the first redistribution layer;
a core section between the first redistribution layer and the second redistribution layer, the core section comprising a central region and a peripheral region at least partially surrounding the central region;
a plurality of central through vias vertically penetrating the core section in the central region;
a plurality of peripheral through vias vertically penetrating the core section in the peripheral region;
a dummy structure in the first redistribution layer and on a bottom surface of the core section; and
a bridge chip in the second redistribution layer and on a top surface of the core section,
wherein a first width of each of the plurality of central through vias is greater than a second width of each of the plurality of peripheral through vias, and
wherein a thermal conductance of each of the plurality of central through vias is greater than a thermal conductance of each of the plurality of peripheral through vias.

13. The semiconductor package of claim 12, wherein a thermal conductance of the bridge chip is greater than a thermal conductance of the second redistribution layer.

14. The semiconductor package of claim 12, wherein the plurality of central through vias are electrically insulated from the first redistribution layer and the second redistribution layer.

15. The semiconductor package of claim 12, wherein the second redistribution layer at least partially covers the bridge chip and the top surface of the core section.

16. The semiconductor package of claim 12, wherein the first redistribution layer at least partially covers the dummy structure and the bottom surface of the core section, and
wherein the dummy structure is electrically floated from the first redistribution layer.

17. The semiconductor package of claim 12, wherein a material of the bridge chip is the same as a material of the dummy structure.

18. A semiconductor package comprising:
a package substrate;
a first semiconductor chip on the package substrate;
a chip stack on the package substrate and horizontally spaced apart from the first semiconductor chip, the chip stack comprising a plurality of second semiconductor chips that are vertically stacked; and
a molding layer on the package substrate, the molding layer at least partially surrounding the first semiconductor chip and the chip stack,
wherein the package substrate comprises:
a core section;
a plurality of through vias vertically penetrating the core section;
a first redistribution layer on a bottom surface of the core section;
a bridge chip on a top surface of the core section; and
a second redistribution layer at least partially covering the bridge chip and the top surface of the core section, and
wherein a thermal conductance of the bridge chip is greater than a thermal conductance of the second redistribution layer.

19. The semiconductor package of claim 18, further comprising a dummy structure on the bottom surface of the core section and at least partially covering the first redistribution layer,
wherein a thermal conductance of the dummy structure is greater than a thermal conductance of the first redistribution layer.

20. The semiconductor package of claim 19, wherein the core section comprises:
a central region in which the bridge chip and the dummy structure are provided; and
a peripheral region at least partially surrounding the central region,
wherein a first width of each of the plurality of through vias in the central region is greater than a second width of each of the plurality of through vias in the peripheral region, and
wherein a thermal conductance of each of the plurality of through vias in the central region is greater than a thermal conductance of each of the plurality of through vias in the peripheral region.
